(19) United States
(12) Patent Application Publication
(10) Pub. No.: US 2007/0020955 A1
(43) Pub. Date: Jan. 25, 2007

(54) Fabrication method of composite metal oxide dielectric film, and composite metal oxide dielectric film fabricated thereby

(75) Inventors: Won Hoon Song, Seoul (KR); Yul Kyo Chung, Yongin (KR); Sung Taek Lim, Incheon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/490,230

(22) Filed: Jul. 21, 2006

(30) Foreign Application Priority Data
Jul. 22, 2005 (KR) 10-2005-0066943
Oct. 21, 2005 (KR) 10-2005-0099536

(51) Int. Cl. H01L 21/31

(52) U.S. Cl. 438/778

(57) ABSTRACT

The invention relates to a fabrication method of a composite metal oxide dielectric film containing at least two metallic elements on a substrate, and a composite metal oxide dielectric film fabricated thereby. The method includes: forming an amorphous film containing at least one of the metallic elements; preparing a hydrothermal solution where a precursor of the remaining element of the metallic elements is mixed; immersing the amorphous film into the hydrothermal solution; and hydrothermally treating the amorphous film so that the remaining one of the metallic elements is synthesized to the amorphous film, thereby forming a crystallized composite metal oxide film.

### RELATED APPLICATION

The present application is based on and claims priority from Korean Application No. 10-2005-0066943, filed Jul. 22, 2005, and 10-2005-0099536, filed Oct. 21, 2005, the disclosures of which are hereby incorporated by reference herein in its entirety.

### BACKGROUND OF THE INVENTION

1. Field of the Invention

The present invention relates to a composite metal oxide dielectric film, and more particularly, a method of fabricating a dielectric film containing at least two metallic elements such as BaTiO₃ by using film formation and hydrothermal synthesis, and a dielectric film fabricated thereby.

2. Description of the Related Art

In general, miniaturization of electronic devices tends to make more semiconductor active devices imbedded gradually. In addition, as the active devices have more input/output terminals, more spaces for passive devices are also required around the terminals. In particular, it is necessary to arranged passive devices such as a decoupling capacitor most adjacent to input terminals in order to reduce inductance owing to rising operational frequency.

In order to solve such demands, imbedded capacitor technologies have been proposed recently and are under active study.

Such an imbedded capacitor is internally mounted in a memory card, a PC motherboard and various RF modules. The imbedded capacitor can reduce the size of products remarkably and be arranged in vicinity to input terminals of an active device. This can advantageously minimize the length of signal lines, thereby reducing inductance remarkably.

In order to realize such an imbedded capacitor, there is required a technology for forming a dielectric film of high electric constant as a PCB laminated structure. However, the main material of the PCB such as polymeric composite is weak to heat, and thus can be hardly made into a dielectric film of high dielectric constant.

That is, a dielectric film formed generally at a low temperature has a low dielectric constant (e.g., 5 or less) owing to its perfect crystallinity even though formed through spin coating. As a result, after a film is formed, it should be additionally crystallized through heat treatment in order to improve dielectric constant. However, such heat treatment is performed typically at a high temperature of 400° C. or higher, which may transform or damage a PCB.

As described above, low temperature processing can hardly produce a dielectric film of high dielectric constant, and such a problem has been recognized as a severe technical barrier to practical use of embedded capacitors.

### SUMMARY OF THE INVENTION

The present invention has been made to solve the foregoing problems of the prior art and therefore an object of the present invention is to provide a fabrication method of a composite oxide dielectric film, which forms a film structure containing some metallic element through a low temperature film formation and then synthesizes the film structure with the other metallic element into a crystal structure through hydrothermal synthesis, and a dielectric film fabricated thereby.

According to an aspect of the invention for realizing the object, there is provided a fabrication method of a composite metal oxide dielectric film containing at least two metallic elements on a substrate, the method comprising steps of: forming an amorphous film containing at least one of the metallic elements; preparing a hydrothermal solution where a precursor of the remaining element of the metallic elements is mixed; immersing the amorphous film into the hydrothermal solution; and hydrothermally treating the amorphous film so that the remaining element of the metallic elements is synthesized to the amorphous film, thereby forming a crystallized composite metal oxide film.

Preferably, the substrate is one selected from the group consisting of a foil, a wafer and a Copper Clad Laminate (CCL) substrate. Furthermore, the foil comprises one selected from the group consisting of Ti, Cu and Al, and is preferably a Cu foil.

Preferably, the composite metal oxide comprises one selected from the group consisting of BaTiO₃, BaₓSr₁₋ₓTiO₃, where 0<x<1, and PbZrₓTi₁₋ₓO₃, where 0<x<1, in which the amorphous film comprises one of Ti and TiO₂.

Preferably, the composite metal oxide comprises BaTiO₃, in which the amorphous film comprises one selected from the group consisting of Ti and TiO₂, and the precursor of the remaining element of the metallic elements comprises at least one selected from the group consisting of BaCl₂, Ba(NO₃)₂ and Ba(OH)₃.

According to an embodiment of the invention, the amorphous film-forming step may comprise sol-gel spin coating. Alternatively, the amorphous film-forming step may comprise sputtering at a low temperature of about 400° C. or less.

In addition, the hydrothermal treating step is carried out at a temperature preferably of about 400° C. or less, and more preferably of about 150° C. to about 280° C.

Furthermore, the hydrothermal treating step is carried out so that the amorphous film partially remains underlying the composite metal oxide film so that the remaining amorphous film part can act as a barrier layer.

According to another aspect of the invention for realizing the object, there is provided a composite metal oxide dielectric film fabricated as above, which may have a dielectric constant of 50 or more.

According to further another aspect of the invention for realizing the object, there is provided a composite metal oxide dielectric film comprising composite metal oxide containing at least two metallic elements, which is formed on a substrate.

Preferably, the substrate is one selected from the group consisting of a foil, a wafer and a Copper Clad Laminate (CCL) substrate. In addition, the foil comprises one selected from the group consisting of Ti, Cu and Al, and preferably, the foil is a Cu foil.

The composite metal oxide may comprise one selected from the group consisting of BaTiO₃, BaₓSr₁₋ₓTiO₃, where 0<x<1, and PbZrₓTi₁₋ₓO₃, where 0<x<1, and may preferably comprise BaTiO₃.

Furthermore, an amorphous film may be disposed underlying the composite metal oxide dielectric film, and the amorphous film may be one of Ti and TiO₂.

According to an aspect of the invention, a novel fabrication method of a metal oxide dielectric film is provided, which can be performed at a low temperature, and in which an amorphous metal oxide film containing some metallic element is formed through a low temperature film formation, and the remaining metallic element is synthesized onto the amorphous metal oxide film through hydrothermal synthesis, causing crystallization. Furthermore, a PCB fabricated thereby can be used availably as an embedded capacitor.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a process flowchart illustrating a fabrication method of a composite metal oxide dielectric film according to the invention;

FIG. 2 is an XRD analysis result of a BaTiO₃ film fabricated according to a first embodiment of the invention;

FIG. 3 shows SEM pictures taken from the surface and cross section of a BaTiO₃ film fabricated according to the first embodiment of the invention;

FIG. 4 is graphs illustrating dielectric properties of a BaTiO₃ film fabricated according to the first embodiment of the invention;

FIG. 5 shows SEM pictures taken from the surface and cross section of a BaTiO₃ film fabricated according to a second embodiment of the invention;

FIG. 6 is graphs illustrating dielectric properties of a BaTiO₃ film fabricated according to the second embodiment of the invention;

FIG. 7 shows SEM pictures taken from the surface and cross section of a BaTiO₃ film fabricated according to a third embodiment of the invention;

FIG. 8 is graphs illustrating dielectric properties of a BaTiO₃ film fabricated according to the third embodiment of the invention;

FIG. 9 shows SEM pictures taken from the surface and cross section of a BaTiO₃ film fabricated according to a fourth embodiment of the invention; and

FIG. 10 is graphs illustrating dielectric properties of a BaTiO₃ film fabricated according to the fourth embodiment of the invention.

### DETAILED DESCRIPTION OF THE PREFERRED EMBODIMENT

The present invention will now be described more fully hereinafter with reference to the accompanying drawings, in which preferred embodiments of the invention are shown.

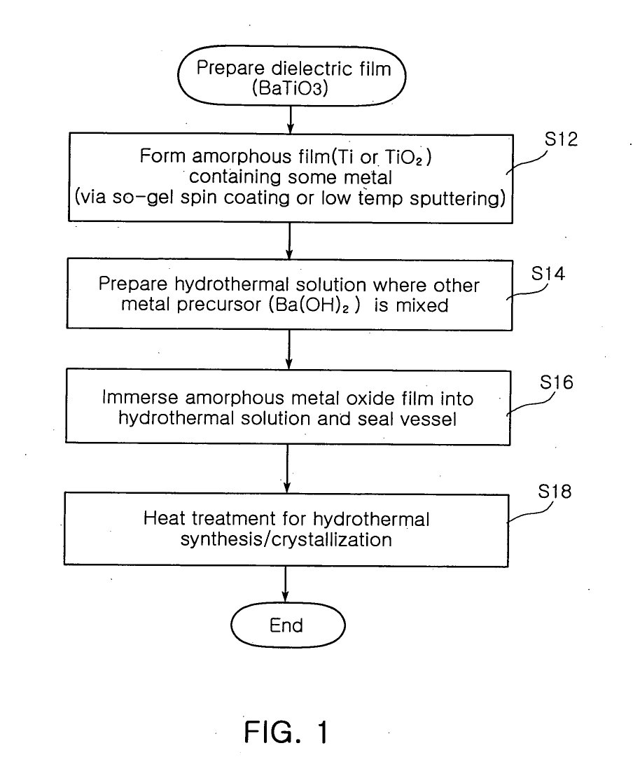

FIG. 1 is a process flowchart illustrating a fabrication method of a composite metal oxide dielectric film according to the invention.

First, the fabrication method of a composite metal oxide dielectric film according to the invention starts with a step of forming an amorphous metal film on a substrate in S12. Here, the amorphous metal film contains only some of whole metallic elements of a desired composite metal oxide (hereinafter will be also referred to as “some metallic element(s)”). For example, in case of attempting to fabricate a BaTiO₃ film, a Ti or TiO₂ film is formed through a typical low temperature film formation. Examples of the low temperature film formation available in this step may include sol-gel spin coating, sputtering capable of being performed at a low temperature (e.g., 400° C. or less), Chemical Vapor Deposition (CVD) and Pulse Laser Deposition (PLD). In this step, since the metal oxide film is obtained from the lower temperature film formation, it is amorphous rather than crystalline. However, the metal oxide film can be formed into a film structure with desirable size and thickness.

The substrate with the amorphous film formed thereon is not limited to specific types, and may be selected from for example foil, wafer, Copper Clad Laminates (CCL) and so on. Where a foil substrate is used out of these substrate types, Cu foil is more preferable than Ti or Al foil since it can further save manufacturing cost.

Next, a hydrothermal solution with metal precursor mixed therein is prepared in S14. Here, the precursor is composed of the other element(s) of the desired composite metal oxide (hereinafter will also be referred to as “the remaining element(s)”). This step may be understood as a process for preparing the hydrothermal solution for hydrothermal synthesis. The metal precursor used herein may be selected from various types of metal salt or metal alkoxide. For example, in case of forming an amorphous Ti or TiO₂ film to fabricate a BaTiO₃ film as in the example of the preceding step, metal salt such as BaCl₂ and/or Ba(NO₃)₂ or metal alkoxide such as Ba(OH)₃ may be used to prepare a suitable hydrothermal solution.

Then, the amorphous metal film is disposed into a vessel where the prepared hydrothermal solution is contained, and the vessel is hermetically sealed in S16. This step may be understood as immersion and sealing process for enabling hydrothermal synthesis. The reason for immersing the amorphous metal film into the hydrothermal solution and then hermetically sealing the vessel is to obtain pressurization condition necessary for crystallization in following heat treatment.

Finally, the metal film immersed into the hydrothermal solution is hydrothermally treated. In this hydrothermal synthesis, ions of the other metallic element are provided from the metal precursor of the hydrothermal solution into the amorphous metal film and synthesized with the amorphous metal film so that a synthesized amorphous metal oxide film portion is crystallized.

As a result, the amorphous metal film is formed into desirable crystallized composite metal oxide. For example, when Ba⁺ of the hydrothermal solution is synthesized onto the immersed Ti or TiO₂ film, crystallization takes place, thereby forming a BaTiO₃ film. Such hydrothermal synthesis performed as above maintains a basic film structure of the amorphous metal oxide formed in the preceding step S12, and thus can provide a desired dielectric film structure.

The hydrothermal synthesis of this step is performed at a temperature of preferably 400° C. or less, and more preferably, of 150° C. to 280° C. Therefore, the method of the invention can be applied to form a dielectric film on a polymeric body such as in fabrication of a PCB.

In conventional hydrothermal synthesis, co-precipitate is produced by using at least two types of metal salt or metal alkoxide and hydrothermally synthesized into dielectric powder. However, the hydrothermal synthesis of this invention performs hydrothermal synthesis on the amorphous metal oxide film of some metallic element obtained through low temperature film formation by using the hydrothermal solution containing metal salt or metal alkoxide of the other metallic element in order to convert the amorphous metal oxide film into composite metal oxide dielectric film.

Furthermore, since the dielectric film is crystallized in the hydrothermal synthesis when produced according to this embodiment of the invention, it can typically have a dielectric constant of 50 or more, and a high dielectric constant of 1000 or more according to process condition.

The composite metal oxide dielectric film of the invention is made of composite metal oxide formed on a substrate and containing at least two metallic elements.

The substrate may be selected from the group consisting of a foil, a wafer and a CCL substrate. The foil may be made of one selected from Ti, Cu and Al, and preferably be a Cu foil.

Furthermore, the composite metal oxide may be selected from the group consisting of BaTiO₃, BaₓSr₁₋ₓTiO₃, where 0<x<1, and PbZrₓTi₁₋ₓO₃, where 0<x<1, and preferably is BaTiO₃.

Moreover, an amorphous film may be formed as a barrier layer underlying the composite metal oxide dielectric film, and preferably be made of Ti or TiO₂.

The invention will now be described in more detail with reference to several examples.

Four examples below were commonly carried out to produce BaTiO₃ composite metal oxide dielectric film, whereas amorphous metal oxide films were formed by different processes with different substrate types.

### EXAMPLE 1

In Example 1, an amorphous metal oxide film of TiO₂ was formed with a thickness of about 200 nm by using sol-gel method (spin coating). Ti-alkoxide monomer precursor was applied on a Pt/Ti/SiO₂/Si wafer substrate. β-diketone and CH₃COOH were used with adequate quantities as a low temperature stabilizer in the spin coating. The spin coating for the formation of a TiO₂ film was repeated 3 times for 20 secs with a rotation speed of 4000 rpm, and the coated film was dried at 200° C. for 30 mins through hot plate baking.

Then, a hydrothermal solution of 1M Ba(OH)₂ was prepared at a quantity of 50 ml, and seated in an autoclave having 1 l capacity to immerse the TiO₂ film. With the TiO₂ film immersed, the autoclave was hermetically sealed, and then hydrothermal synthesis was performed at 250° C. for 5 hrs.

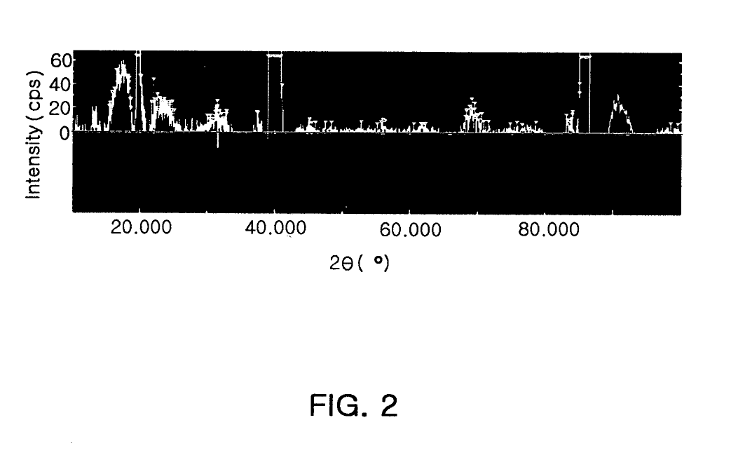

XRD analysis was performed on the composite metal oxide film produced as above. Analysis result is shown in FIG. 2, where the peak appearing in vicinity of 30° shows clearly the formation of a BaTiO₃ film.

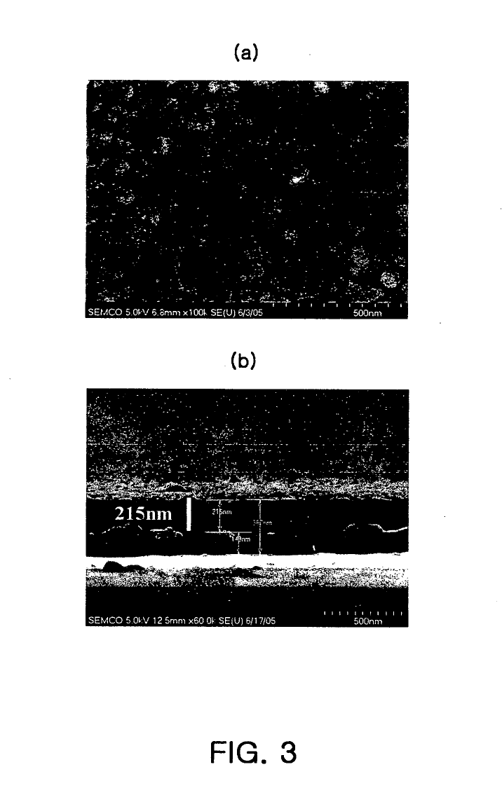

FIG. 3 shows SEM pictures taken from the surface and cross section of a BaTiO₃ film fabricated according to the first embodiment of the invention.

Referring to FIG. 3(a), it is found that the surface of the BaTiO₃ film is composed of grains of about 100 nm. Furthermore, as shown in FIG. 3(b), the crystallized BaTiO₃ film has a thickness of about 215 nm. (A lower layer means a Pt electrode).

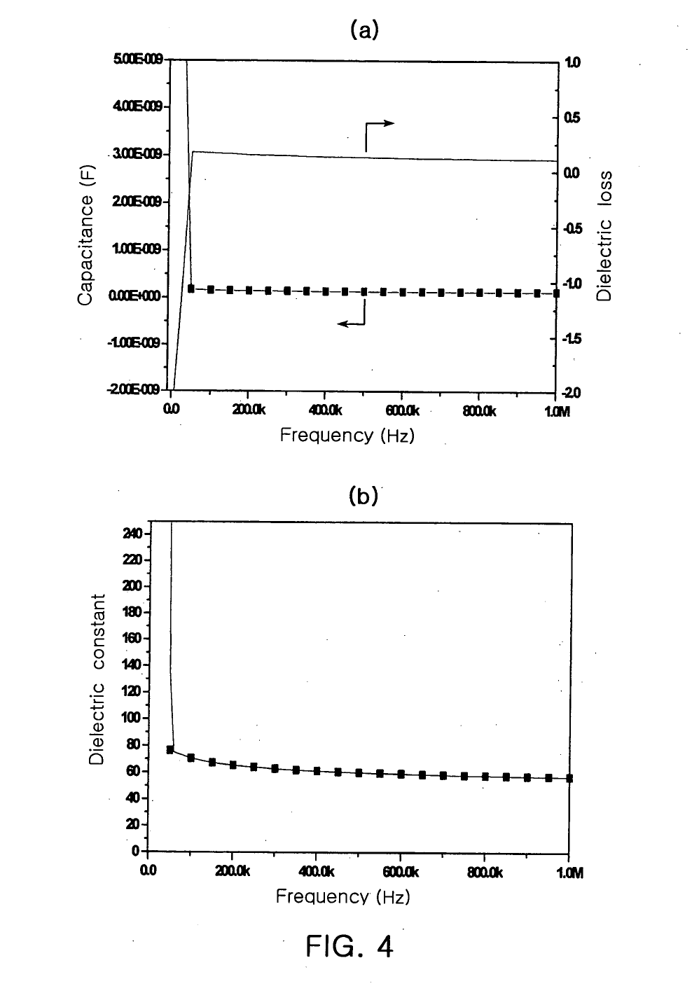

FIG. 4 is graphs illustrating dielectric properties of a BaTiO₃ film fabricated according to the first embodiment of the invention.

It is found that the BaTiO₃ film produced in Example 1 is made of a high quality dielectric film which has a low dielectric loss of about 0.11 in 0.1 MHz to 1 MHz bandwidth as seen in FIG. 4(a) and a relatively high electric constant of 60 or more in the same frequency bandwidth as seen in FIG. 4(b).

### EXAMPLE 2

In Example 2, a metal oxide film of TiO₂ was formed with a thickness of about 650 nm on a Pt/Ti/SiO₂/Si wafer substrate by using sputtering. The sputtering was performed at a room temperature, resulting in an amorphous metal oxide film of TiO₂.

Next, a hydrothermal synthesis was performed similarly to Example 1. That is, a hydrothermal solution of 1M Ba(OH)₂ was prepared at a quantity of 50 ml, and seated in an autoclave having 1 l capacity to immerse the TiO₂ film. With the TiO₂ film immersed, the autoclave was hermetically sealed, and then hydrothermal synthesis was performed at 250° C. for 5 hrs.

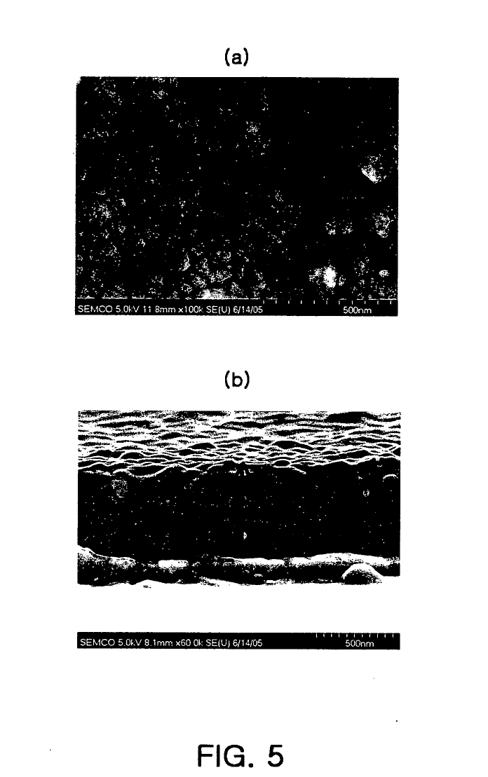

FIG. 5 shows SEM pictures taken from the surface and cross section of a BaTiO₃ film fabricated according to a second embodiment of the invention.

As shown in FIG. 5(a), it is found that the surface of the BaTiO₃ film is composed of grains of about 100 nm, having crystalline appearance. Referring to the cross-sectional configuration of the film shown in FIG. 5(b), although amorphous TiO₂ partially remains in vicinity of the substrate surface, the crystallized BiTiO₃ film was formed with a thickness of about 625 nm from the top surface. This result shows that the hydrothermal synthesis was performed more effectively in the sputtered amorphous oxide film than in Example 1.

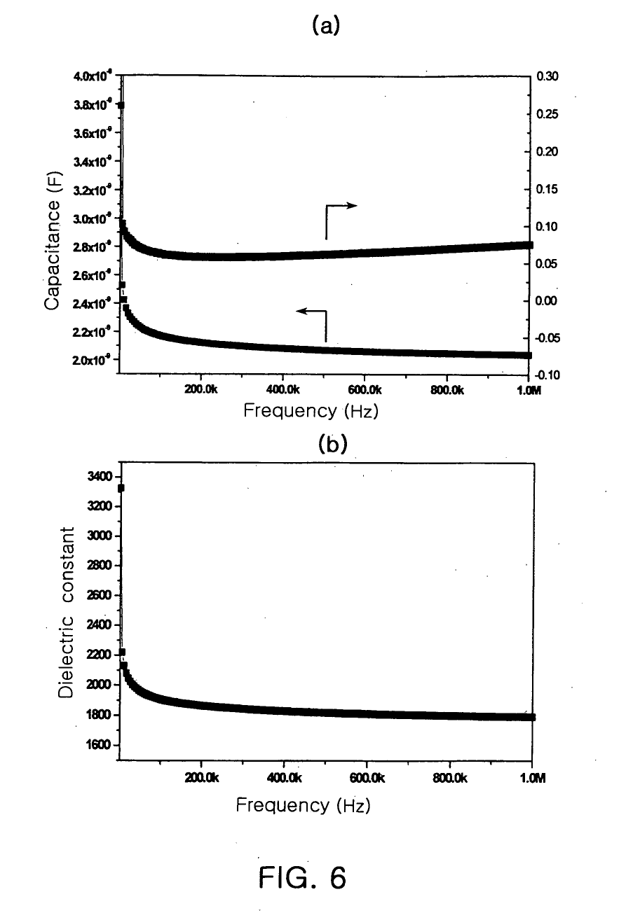

FIG. 6 is graphs illustrating dielectric properties of a BaTiO₃ film fabricated according to the second embodiment of the invention.

It is found that the BaTiO₃ film produced in Example 2 is made of a high quality dielectric film which has a low dielectric loss of about 0.07 in 0.1 MHz to 1 MHz bandwidth as seen in FIG. 6(a) and a relatively high electric constant of 1700 in the same frequency bandwidth as seen in FIG. 6(b). This result also shows that the resultant dielectric film has more excellent dielectric characteristics over Example 1, when produced using the sputtered amorphous oxide film.

### EXAMPLE 3

In Example 3, a metal film of Ti was formed with a thickness of about 100 nm on a Si wafer substrate by using sputtering. The sputtering was performed at a room temperature, resulting in an amorphous metal film of Ti.

Next, a hydrothermal synthesis was performed similarly to Example 1. That is, a hydrothermal solution of 1M Ba(OH)₂ was prepared at a quantity of 50 ml, and seated in an autoclave having 1 l capacity to immerse the Ti film. With the Ti film immersed, the autoclave was hermetically sealed, and then hydrothermal synthesis was performed at 250° C. for 5 hrs.

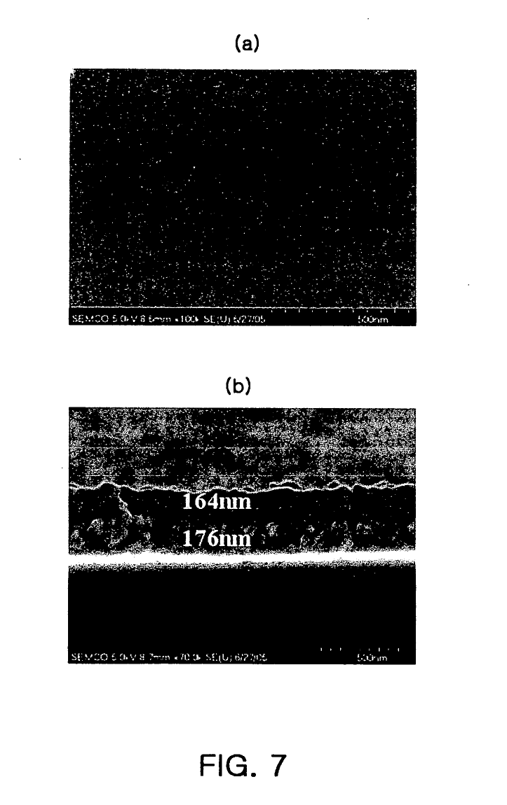

FIG. 7 shows SEM pictures taken from the surface and cross section of a BaTiO₃ film fabricated according to a third embodiment of the invention.

As shown in FIG. 7(a), it is found that the surface of the BaTiO₃ film is composed of grains of about 100 nm, showing crystalline appearance. Referring to the cross-sectional configuration of the film shown in FIG. 7(b), amorphous Ti partially remains with a thickness of about 176 nm in vicinity of the substrate surface, and the crystallized BiTiO₃ film was formed with a thickness of about 164 nm from the top surface.

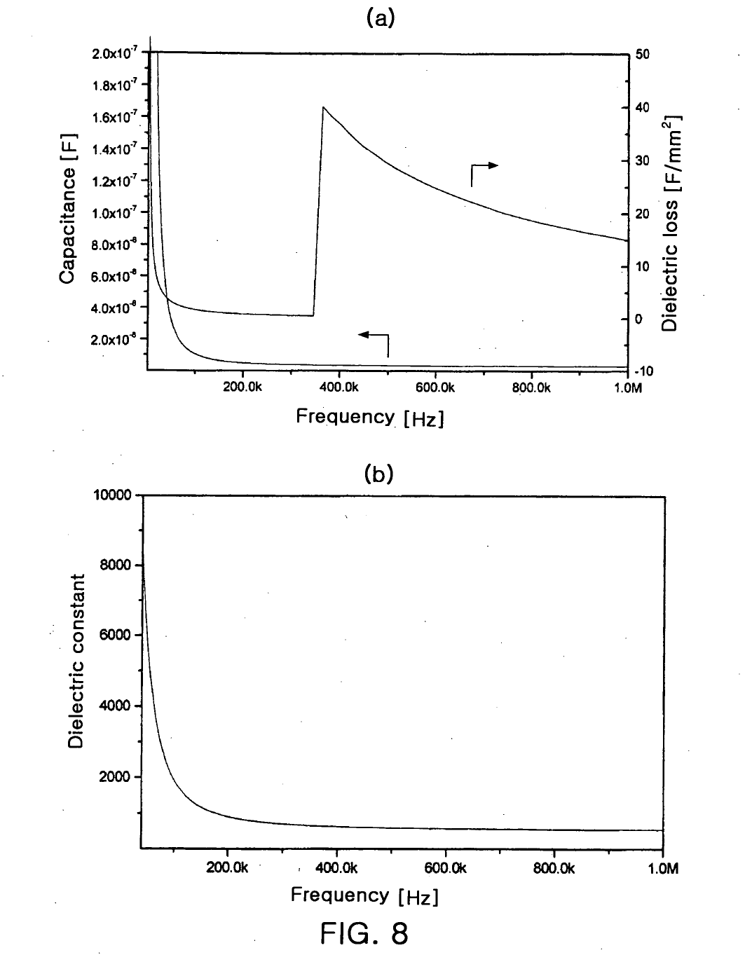

FIG. 8 is graphs illustrating dielectric properties of a BaTiO₃ film fabricated according to the third embodiment of the invention.

It is found that the BaTiO₃ film produced in Example 3 is made of a high quality dielectric film which has a low dielectric loss of about 15 in 0.1 MHz to 1 MHz bandwidth as seen in FIG. 8(a) and a relatively high electric constant of 550 in the same frequency bandwidth as seen in FIG. 8(b).

### EXAMPLE 4

In Example 4, a metal oxide film of TiO₂ was formed with a thickness of about 400 nm on a Pt/Cu/SiO₂/Si wafer substrate by using sputtering. The sputtering was performed at a room temperature, resulting in an amorphous metal oxide film of TiO₂.

Next, a hydrothermal synthesis was performed similarly to Example 1. That is, a hydrothermal solution of 1M Ba(OH)₂ was prepared at a quantity of 50 ml, and seated in an autoclave having 1 l capacity to immerse the TiO₂ film. With the TiO₂ film immersed, the autoclave was hermetically sealed, and then hydrothermal synthesis was performed at 250° C. for 5 hrs.

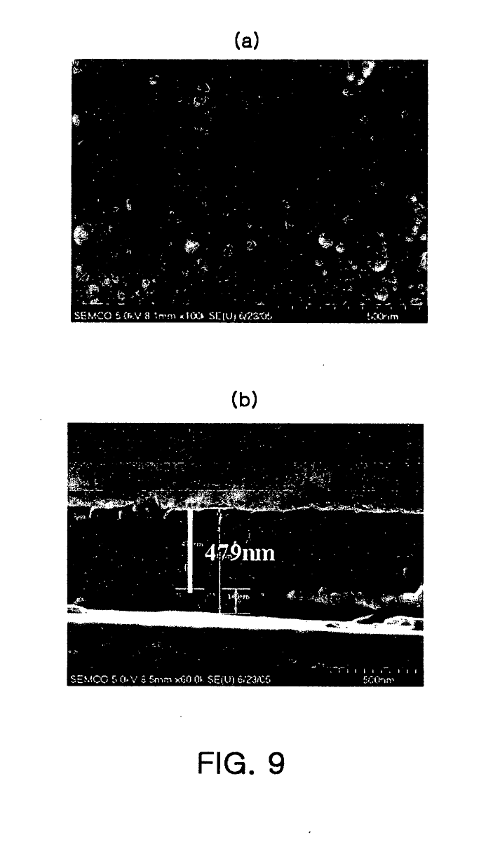

FIG. 9 shows SEM pictures taken from the surface and cross section of a BaTiO₃ film fabricated according to a fourth embodiment of the invention.

As shown in FIG. 9(a), it is found that the surface of the BaTiO₃ film is composed of grains sized smaller than about 10 nm, showing crystalline appearance. Referring to the cross-sectional configuration of the film shown in FIG. 9(b), although amorphous TiO₂ partially remains in vicinity of the substrate surface, the crystallized BiTiO₃ film was formed with a thickness of about 479 nm from the top surface.

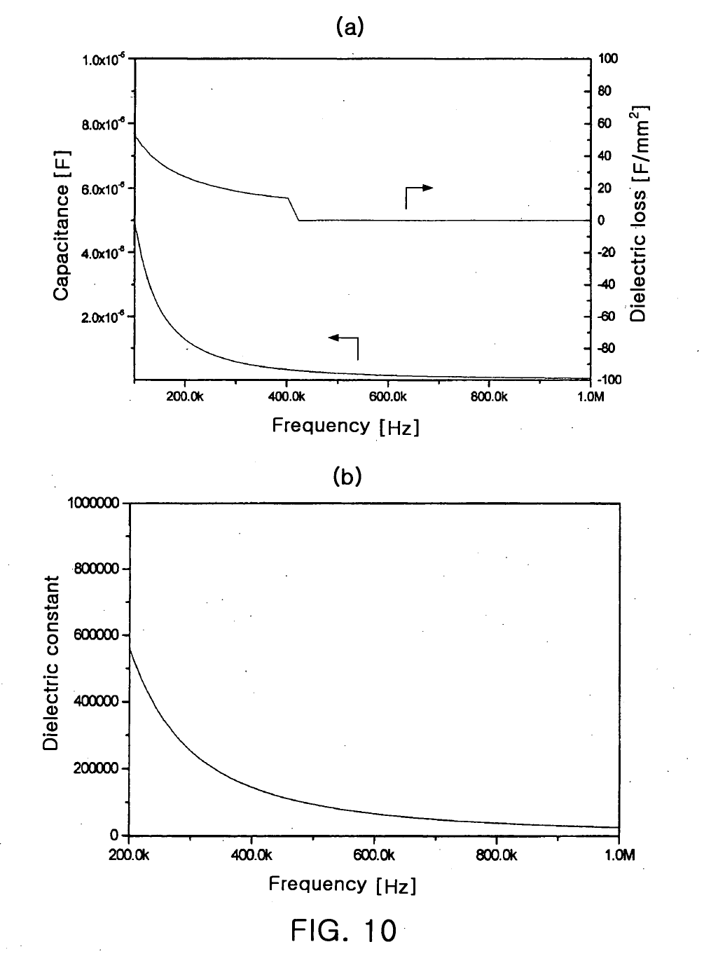

FIG. 10 is graphs illustrating dielectric properties of a BaTiO₃ film fabricated according to the fourth embodiment of the invention.

It is found that the BaTiO₃ film produced in Example 4 is made of a high quality dielectric film which has a low dielectric loss of about 0.019 in 0.1 MHz to 1 MHz bandwidth as seen in FIG. 10(a) and a relatively high electric constant of 24000 in the same frequency bandwidth as seen in FIG. 10(b).

While the foregoing embodiments of the invention have been described with BaTiO₃ exemplified as the composite metal oxide dielectric film, the invention may be applied as a fabrication method of other composite metal oxide dielectric layers containing at least two metallic elements.

For example, this disclosure may be applied to BaₓSr₁₋ₓTiO₃, where 0<x<1 and PbZrₓTi₁₋ₓO₃, where 0<x<1, which are dielectric films containing three types of metallic elements. Here, a desired composite metal oxide dielectric film may be produced by forming an amorphous Ti or TiO₂ film through low temperature film formation, and then performing hydrothermal synthesis with a hydrothermal solution containing Ba and Sr precursor or Pb and Zr precursor.

Furthermore, according to a specific embodiment of the invention, the film may be formed entirely into BaTiO₃ according to conditions such as hydrothermal synthesis time since the hydrothermal synthesis is performed starting from the exposed top surface of the amorphous Ti or TiO₂ film. Alternatively, it is possible to intentionally leave a part of amorphous Ti or TiO₂ in a lower region. Here, the remaining layer may form a dielectric layer heterogeneous from BaTiO₃, be expected to function as a barrier layer that reduces leakage current.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

As described hereinbefore, certain embodiments of the invention can form an amorphous metal oxide film containing some metallic element through a low temperature film formation, and synthesize the other metallic element onto the amorphous metal oxide film through hydrothermal synthesis, causing crystallization, and thus perform the entire process at a low temperature. Thereby, a dielectric film having excellent dielectric characteristics can be easily formed. Such a low temperature formation of high quality dielectric film can be very availably applied to a fabrication method of an embedded capacitor for a PCB.

What is claimed is:

1. A fabrication method of a composite metal oxide dielectric film containing at least two metallic elements on a substrate, the method comprising steps of:
forming an amorphous film containing at least one of the metallic elements;
preparing a hydrothermal solution where a precursor of the other one of the metallic elements is mixed;
immersing the amorphous film into the hydrothermal solution; and
hydrothermally treating the amorphous film so that the remaining element of the metallic elements is synthesized to the amorphous film, thereby forming a crystallized composite metal oxide film.

2. The fabrication method according to claim 1, wherein the substrate is one selected from the group consisting of a foil, a wafer and a Copper Clad Laminate (CCL) substrate.

3. The fabrication method according to claim 2, wherein the foil comprises one selected from the group consisting of Ti, Cu and Al.

4. The fabrication method according to claim 3, wherein the foil is a Cu foil.

5. The fabrication method according to claim 1, wherein the composite metal oxide comprises one selected from the group consisting of BaTiO₃, BaₓSr₁₋ₓTiO₃, where 0<x<1, and PbZrₓTi₁₋ₓO₃, where 0<x<1.

6. The fabrication method according to claim 5, wherein the amorphous film comprises one of Ti and TiO₂.

7. The fabrication method according to claim 5, wherein the composite metal oxide comprises BaTiO₃.

8. The fabrication method according to claim 7, wherein the amorphous film comprises one selected from the group consisting of Ti and TiO₂, and the precursor of the remaining element of the metallic elements comprises at least one selected from the group consisting of BaCl₂, Ba(NO₃)₂ and Ba(OH)₃.

9. The fabrication method according to claim 1, wherein the amorphous film forming step comprises sol-gel spin coating.

10. The fabrication method according to claim 1, wherein the amorphous film forming step comprises sputtering at a low temperature of about 400° C. or less.

11. The fabrication method according to claim 1, wherein the hydrothermal treating step is carried out at a temperature of about 400° C. or less.

12. The fabrication method according to claim 11, wherein the hydrothermal treating step is carried out at a temperature of about 150° C. to about 280° C.

13. The fabrication method according to claim 1, wherein the hydrothermal treating step is carried out so that the amorphous film partially remains underlying the composite metal oxide film.

14. A composite metal oxide dielectric film fabricated according to a method as defined in claim 1, the composite metal oxide dielectric film having a dielectric constant of 50 or more.

15. A composite metal oxide dielectric film comprising composite metal oxide containing at least two metallic elements, the composite metal oxide dielectric film formed on a substrate.

16. The composite metal oxide dielectric film according to claim 15, wherein the substrate is one selected from the group consisting of a foil, a wafer and a Copper Clad Laminate (CCL) substrate.

17. The composite metal oxide dielectric film according to claim 16, wherein the foil comprises one selected from the group consisting of Ti, Cu and Al.

18. The composite metal oxide dielectric film according to claim 17, wherein the foil is a Cu foil.

19. The composite metal oxide dielectric film according to claim 15, wherein the composite metal oxide comprises one selected from the group consisting of BaTiO₃, BaₓSr₁₋ₓTiO₃, where 0<x<1, and PbZrₓTi₁₋ₓO₃, where 0<x<1.

20. The composite metal oxide dielectric film according to claim 19, wherein the composite metal oxide comprises BaTiO₃.

21. The composite metal oxide dielectric film according to claim 15, wherein an amorphous film is disposed underlying the composite metal oxide dielectric film.

22. The composite metal oxide dielectric film according to claim 21, wherein the amorphous film is one of Ti and TiO₂.
